(19) United States
(12) Patent Application Publication
(10) Pub. No.: US 2026/0231774 A1
(43) Pub. Date: Aug. 6, 2026

(54) Semiconductor Device and Method of Forming Stacked AIP Structure

(71) Applicant: JCET STATS ChipPAC Korea Limited, Incheon (KR)

(72) Inventors: SeungHyun Lee, Incheon (KR); Yeojun Yun, Incheon (KR); HeeSoo Lee, Incheon (KR)

(73) Assignee: JCET STATS ChipPAC Korea Limited, Incheon (KR)

(21) Appl. No.: 19/046,111

(22) Filed: Feb. 5, 2025

(51) Int. Cl. H01L 23/552; H01L 21/48; H01L 23/31; H01L 23/538; H01L 25/00; H01L 25/18; H01Q 1/22; H01Q 1/52

(52) U.S. Cl. CPC H10W 42/20; H01Q 1/2283; H01Q 1/526; H10W 70/05; H10W 70/611; H10W 74/124; H10W 90/00; H10W 90/401

(57) ABSTRACT

A semiconductor device has an antenna substrate, an electrical component disposed over the antenna substrate, and a semiconductor assembly disposed over the electrical component. The electrical component has a first active surface and second active surface opposite the first active surface with a conductive via extending between the first active surface and second active surface. An encapsulant is deposited over and around the antenna substate and electrical component. An encapsulant can be deposited over the semiconductor assembly. A portion of the encapsulant is removed to expose the semiconductor assembly. A mask is disposed over the semiconductor assembly. A shielding layer is disposed over and around the antenna substate, electrical component, and semiconductor assembly. The mask blocks the shielding layer from covering a portion of the semiconductor assembly. The mask is removed, and an electrical connector is disposed over the semiconductor assembly previously protected by the mask.

### FIELD OF THE INVENTION

The present invention relates in general to semiconductor devices and, more particularly, to a semiconductor device and method of forming a stacked antenna-in-package (AiP) package structure from separate assemblies with bonding material.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system-in-package (SiP) module for higher density in a small space and extended electrical functionality. Within the SiP module, semiconductor die and IPDs are disposed across a first surface of a substrate for structural support and electrical interconnect. An encapsulant is deposited over the semiconductor die, IPDs, and substrate.

An antenna can be disposed on a second surface of the substrate to provide wireless communication for the SiP module. With the addition of the antenna, the SiP constitutes an AiP. With the semiconductor die and IPDs spread horizontally across the surface of the substrate, no one device can become too large. Otherwise, the semiconductor package may exceed size requirements. Accordingly, present AiP modules limit the size of any one semiconductor device.

### BRIEF DESCRIPTION OF THE DRAWINGS

FIGS. 1a-1e illustrate various semiconductor wafers each with a plurality of semiconductor die separated by a saw street;

FIGS. 2a-2o illustrate a process of forming a AiP module with stacked double-sided electrical component and semiconductor assembly over an antenna interposer;

FIGS. 3a-3c illustrate a process of forming the semiconductor assembly used in FIGS. 2a-2o;

FIGS. 4a-4b illustrate an alternate semiconductor assembly;

FIGS. 5a-5h illustrate another process of forming an AiP module with stacked double-sided electrical component and semiconductor assembly over an antenna interposer; and

FIG. 6 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

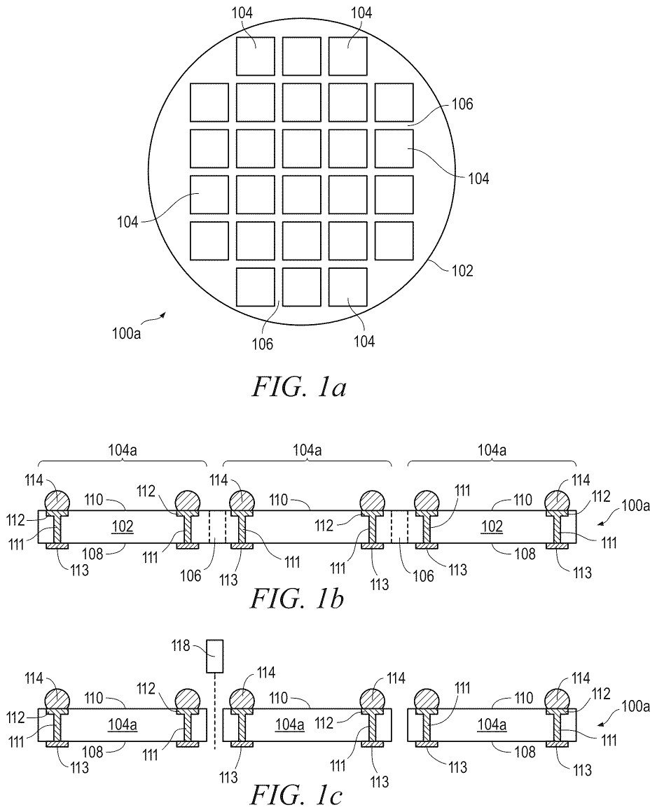

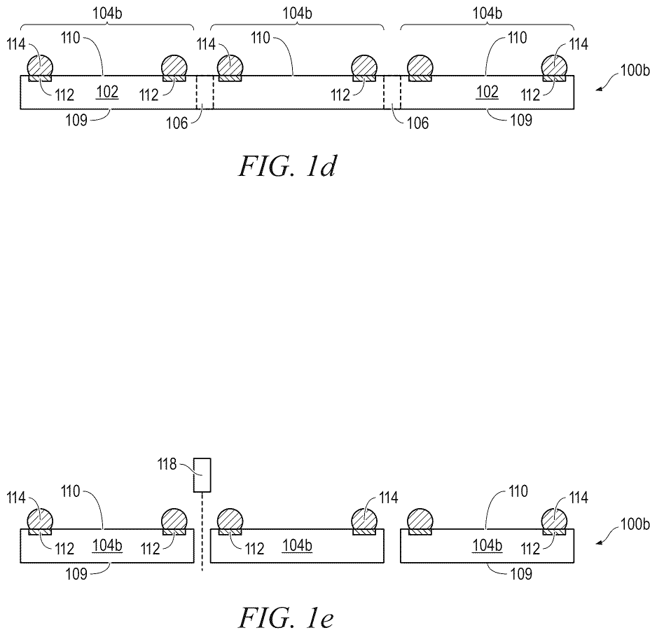

FIG. 1a shows a semiconductor wafer 100a with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104a is formed on wafer 100a separated by a non-active, inter-die wafer area or saw street 106. Saw street 106 provides cutting areas to singulate semiconductor wafer 100a into individual semiconductor die 104a. In one embodiment, semiconductor wafer 100a has a width or diameter of 100-450 millimeters (mm). Semiconductor die 104a can process RF signals transmitted and received through an antenna.

FIG. 1b shows a cross-sectional view of a portion of semiconductor wafer 100a. In one embodiment, each semiconductor die 104a is a double-sided device with active surface 108 and active surface 110 each containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surfaces 108 and 110 to implement analog circuits or digital circuits, such as digital signal processor (DSP), application specific integrated circuits (ASIC), memory, or other signal processing circuit. Semiconductor die 104a may also contain IPDs, such as inductors, capacitors, and resistors, for RF signal processing. In one embodiment, semiconductor die 104a is an RFIC, a monolithic microwave integrated circuit (MMIC), or system-on-chip (SoC) type die.

A plurality of vias is formed through base material 102 between active surface 110 and active surface 108 using an etching process or by laser direct ablation (LDA). The vias are filled with electrically conductive material, such as Al, Cu, Sn, Ni, Au, Ag, or other suitable electrically conductive material, to form conductive vias 111 extending between active surface 110 and active surface 108.

An electrically conductive layer 112 is formed over active surface 110 using PVD, CVD, electrolytic plating, electroless plating process, or other suitable metal deposition process. Likewise, an electrically conductive layer 113 is formed over active surface 108 using PVD, CVD, electrolytic plating, electroless plating process, or other suitable metal deposition process. Conductive layers 112 and 113 can be one or more layers of aluminum (Al), copper (Cu), tin (Sn), nickel (Ni), gold (Au), silver (Ag), or other suitable electrically conductive material. Conductive layers 112 and 113 operate as contact pads electrically connected to the circuits on active surface 110 and 108, respectively.

In FIG. 1c, semiconductor wafer 100a is singulated through saw street 106 using a saw blade or laser cutting tool 118 into individual semiconductor die 104a. The individual semiconductor die 104a can be inspected and electrically tested for identification of known good die or unit (KGD/KGU) post singulation.

Other types of semiconductor die can be made using a wafer 100b, similar to semiconductor wafer 100a. For example, FIG. 1d shows semiconductor die 104b each having a back or non-active surface 109 and active surface 110 containing analog or digital circuits implemented as active devices, passive devices, conductive layers, and dielectric layers formed within the die and electrically interconnected according to the electrical design and function of the die. Components having a similar function are assigned the same reference number. The circuit may include one or more transistors, diodes, and other circuit elements formed within active surface 110 to implement analog circuits or digital circuits, such as DSP, ASIC, memory, or other signal processing circuit. Semiconductor die 104b may also contain IPDs, such as inductors, capacitors, and resistors, for RF signal processing.

In FIG. 1e, semiconductor wafer 100b is singulated through saw street 106 using a saw blade or laser cutting tool 118 into individual semiconductor die 104b. The individual semiconductor die 104b can be inspected and electrically tested for identification of KGD/KGU post singulation.

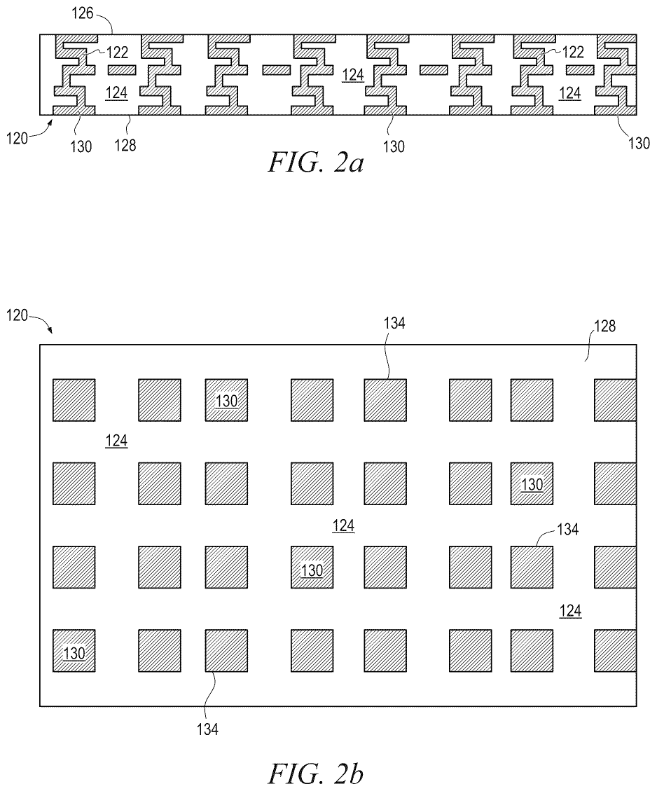

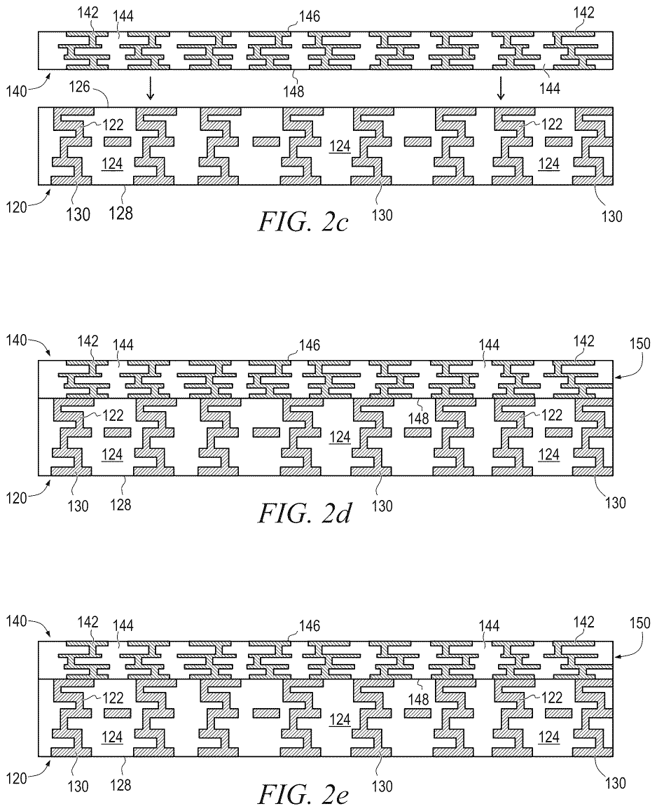

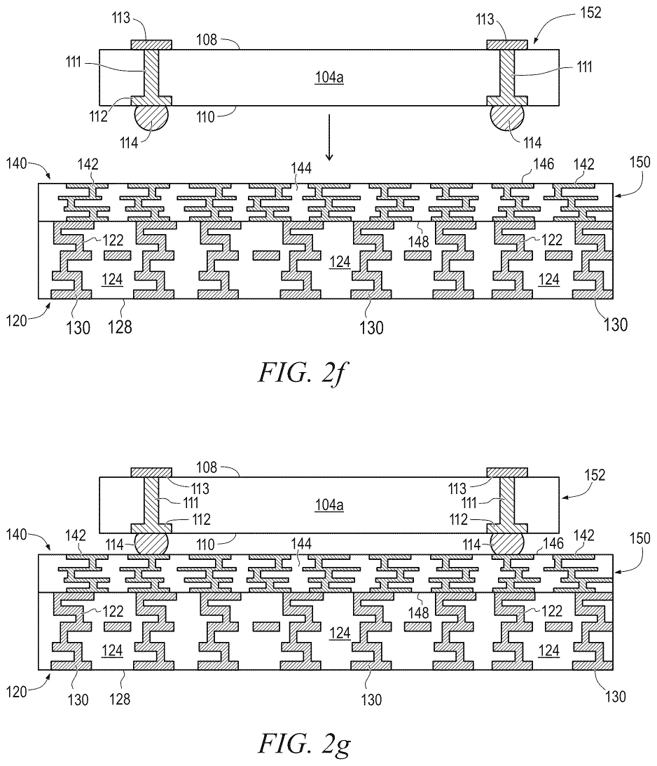

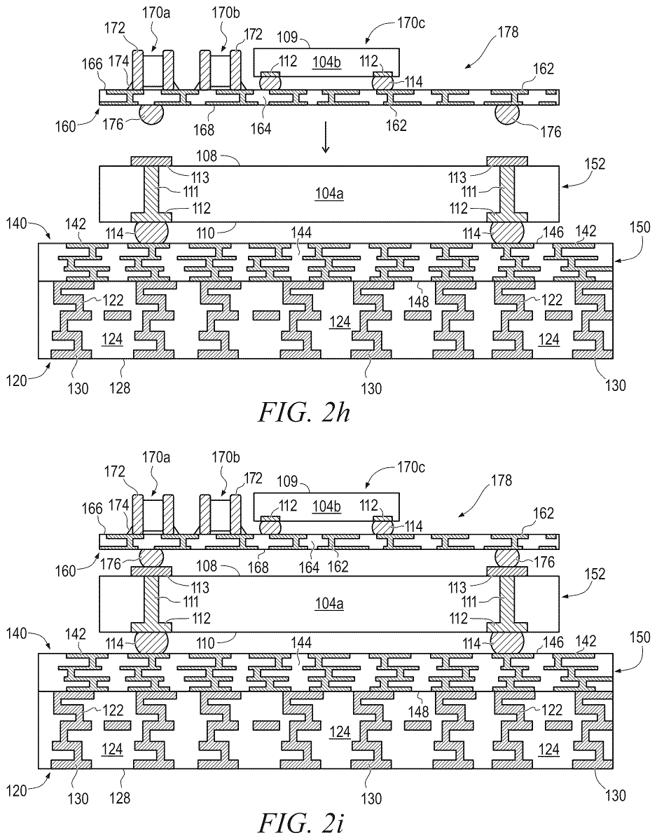

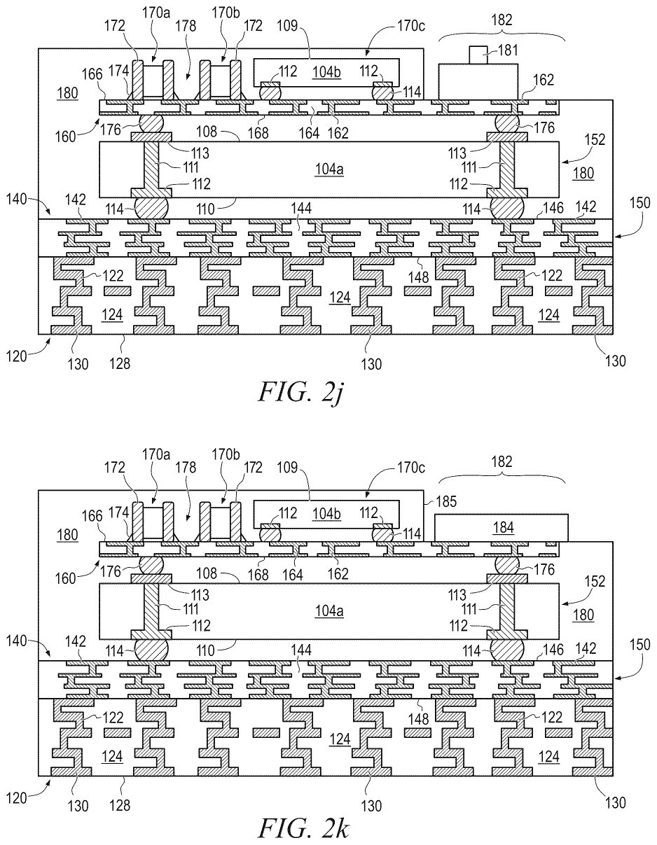

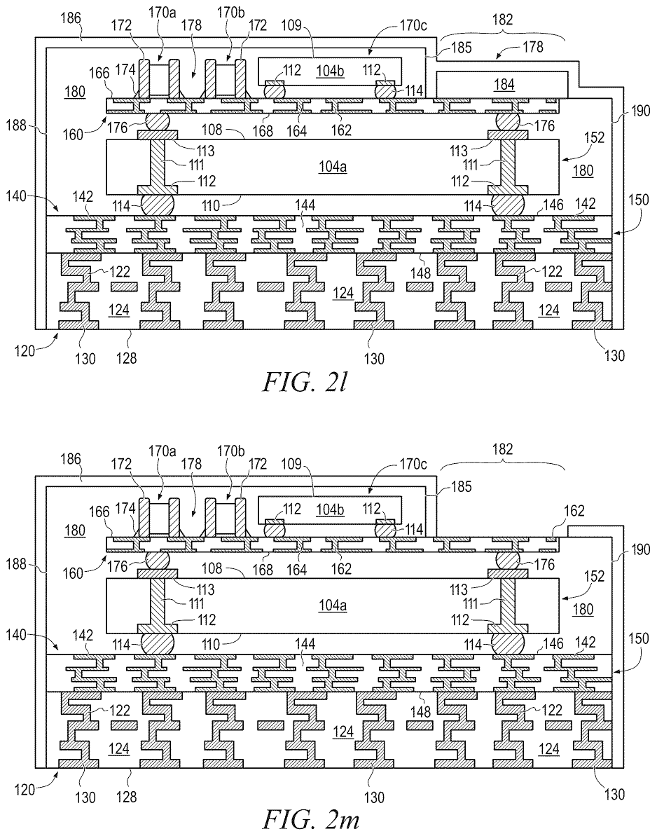

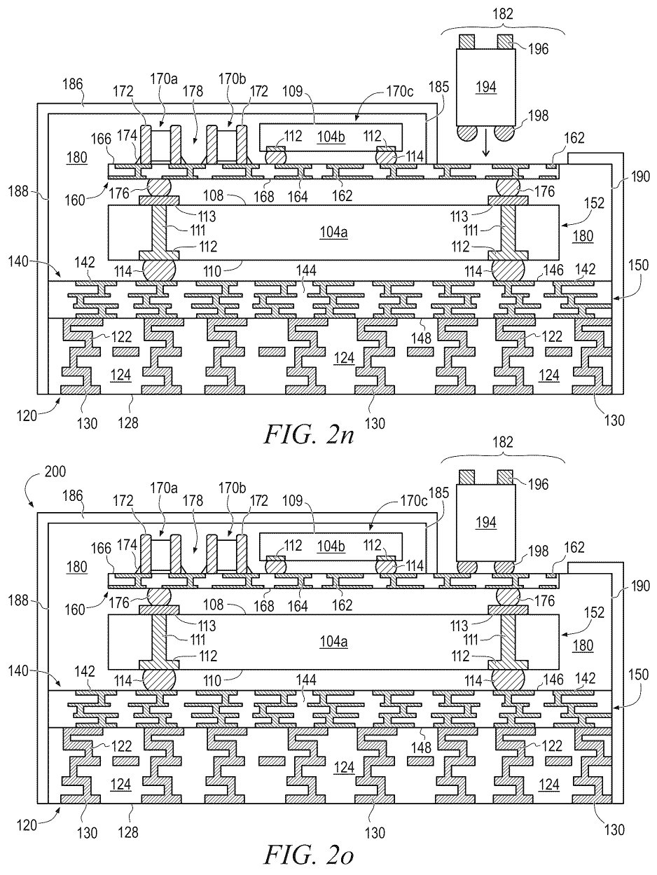

FIGS. 2a-2o illustrate a process of forming an AiP module with stacked double-sided electrical component and semiconductor assembly over an antenna interposer. FIG. 2a shows a cross-sectional view of antenna substrate 120 including core material 124, such as silicon, germanium, aluminum phosphide, aluminum arsenide, gallium arsenide, gallium nitride, indium phosphide, silicon carbide, or other bulk material for structural support. Alternatively, core material 124 can be a multi-layer flexible laminate, ceramic, CCL, glass, or epoxy molding compound. Core material 124 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Antenna substrate 120 has a major surface 126 and major surface 128 opposite surface 126.

An electrically conductive layer 122 is formed over and through antenna substrate 120 using PVD, CVD, electrolytic plating, electroless plating process, or other suitable metal deposition process. Conductive layer 122 can be one or more layers of Al, Cu, Sn, Ni, Au, Ag, or other suitable electrically conductive material. Conductive layer 122 extends vertically and horizontally through antenna substrate 120 to provide electrical interconnect. Conductive layer 122 is also formed over surface 128 and operates as antenna 130 to transmit and receive RF signals. Portions of conductive layer 122 can be electrically common or electrically isolated depending on the design and function of electrical components attached thereto.

FIG. 2b is a top view of one embodiment of antenna 130 on surface 128. Conductive layer 130 includes an array of islands 134 of conductive material suitable to provide transmission and reception of RF signals, i.e., an RF antenna. In particular, antenna islands 134 of conductive layer 122 are exposed from surface 128 to improve RF transmission and reception performance and quality.

FIG. 2c shows a cross-sectional view of interconnect substrate or interposer 140 including one or more conductive layers 142 and one or more insulating layers 144. Conductive layers 142 can be one or more layers of Al, Cu, Sn, Ni, Au, Ag, or other suitable electrically conductive material. Conductive layers 142 can be formed using PVD, CVD, electrolytic plating, electroless plating process, or other suitable metal deposition process. Conductive layers 142 provide horizontal electrical interconnect across the substrate and vertical electrical interconnect between top surface 146 and bottom surface 148 of substrate 140. Portions of conductive layers 142 can be electrically common or electrically isolated depending on the design and function of semiconductor die 104a and 104b and other electrical components. Insulating layers 144 contain one or more layers of SiO2, Si3N4, SiON, Ta2O5, Al2O3, solder resist, polyimide, BCB, PBO, and other material having similar insulating and structural properties. Insulating layers 144 can be formed using PVD, CVD, printing, lamination, spin coating, spray coating, sintering or thermal oxidation. Insulating layers 144 provide isolation between conductive layers 142. There can be multiple conductive layers like 142 separated by insulating layers 144.

Surface 148 of interposer 140 is bonded to surface 126 of antenna substrate 120. Interposer 140 can be bonded to antenna substrate 120 using direct wafer bonding (DWB). In DWB, surface 148 of interposer 140 and surface 126 of antenna substrate 120 are planarized, polished, and cleaned to be flat and smooth, prior to bonding. The lattice structures of interface layers can be aligned to optimize adhesion. Water molecules can be applied to surfaces 148 and 126 to aid in the bonding process. Surface 148 of interposer 140 is brought into contact with surface 126 of antenna substrate 120. DWB is accomplished with chemical bonds and intermolecular interactions at temperature, including van der Waals forces, hydrogen bonds, and covalent bonds, between surface 148 and surface 126. DWB temperatures range from ambient to 100's° C. FIG. 2d shows interposer 140 direct wafer bonded to surface 126 of antenna substrate 120. Alternatively, interposer 140 is bonded to antenna substrate 120 with an adhesive.

In another embodiment, interposer 140 is formed over surface 126 of antenna substrate 120 using a build-up interconnect process. A first conductive layer 142 is formed over surface 126 of antenna substrate 120. A first insulating layer 144 is formed over the first conductive layer 142. A portion of the first insulating layer 144 is removed to expose the first conductive layer 142. A second conductive layer 142 is formed over the first insulating layer 144 and contacts the first conductive layer 142. A second insulating layer 144 is formed over the first insulating layer 144 and second conductive layer 142. A portion of the second insulating layer 144 is removed to expose the second conductive layer 142. A third conductive layer 142 is formed over the second insulating layer 144 and contacts the second conductive layer 142. A third insulating layer 144 is formed over the second insulating layer 144 and third conductive layer 142. A portion of the third insulating layer 144 is removed to expose the third conductive layer 142. The process continues until interposer 140 has all requisite conductive layers 142 and insulating layers 144, as shown in FIG. 2e.

In any case, the combination of antenna substrate 120 and interposer 140 constitute antenna interposer 150 in FIG. 2d or FIG. 2e.

In FIG. 2f, one or more electrical components 152 are disposed over surface 146 of interposer 140. Electrical component 152 is positioned over interposer substrate 140 using a pick and place operation. For example, electrical component 152 can be similar to semiconductor die 104a from FIG. 1c with bumps 114 oriented toward surface 146. Alternatively, electrical component 152 can include other semiconductor die, semiconductor packages, surface mount devices, discrete electrical devices, or IPDs. Bumps 114 are brought into contact with conductive layer 162 and reflowed to make electrical and mechanical interconnect. FIG. 2g shows electrical component 152 disposed on surface 146 of interposer 140. Electrical component 152 may be a relatively large device, such as a double-sided RFIC with interconnecting conductive vias 111, occupying a substantial portion of interposer 140. The large size of electrical component 152 provides for more components on both active surfaces 108 and 110 interconnected by conductive vias 111. The double-sided device is more space efficient and provides a higher density of components per unit area. The large electrical component 152 can replace many smaller components traditionally spread across the surface area of antenna interposer 150. In one embodiment, electrical component 152 occupies over 50% of the surface area of antenna interposer 150. Preferably, electrical component 152 occupies over 60% of the surface area of antenna interposer 150.

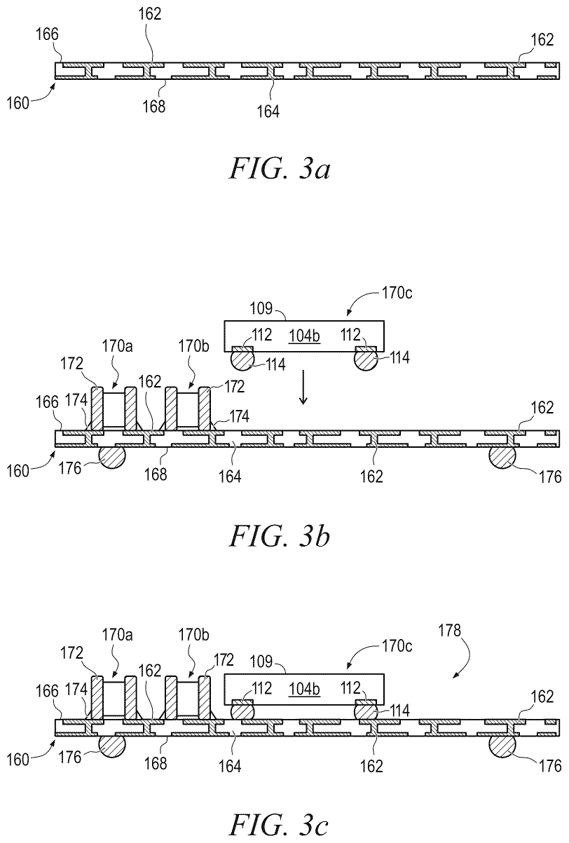

FIG. 3a shows a cross-sectional view of interconnect substrate or interposer 160 including one or more conductive layers 162 and one or more insulating layers 164. Conductive layers 162 can be one or more layers of Al, Cu, Sn, Ni, Au, Ag, or other suitable electrically conductive material. Conductive layers 162 can be formed using PVD, CVD, electrolytic plating, electroless plating process, or other suitable metal deposition process. Conductive layers 162 provide horizontal electrical interconnect across the substrate and vertical electrical interconnect between top surface 166 and bottom surface 168 of substrate 160. Portions of conductive layers 162 can be electrically common or electrically isolated depending on the design and function of semiconductor die 104a and 104b and other electrical components. Insulating layers 164 contain one or more layers of SiO2, Si3N4, SiON, Ta2O5, Al2O3, solder resist, polyimide, BCB, PBO, and other material having similar insulating and structural properties. Insulating layers 164 can be formed using PVD, CVD, printing, lamination, spin coating, spray coating, sintering or thermal oxidation. Insulating layers 164 provide isolation between conductive layers 162. There can be multiple conductive layers like 162 separated by insulating layers 164.

In FIG. 3b, a plurality of electrical components 170a, 170b, and 170c is disposed over surface 166 of interposer 160. Electrical components 170a-170c are each positioned over interposer substrate 160 using a pick and place operation. For example, electrical components 170a and 170b can be discrete semiconductor devices, such as resistor, capacitors, inductors, diodes, and transistors, with terminals 172 connected to conductive layer 162 with solder or conductive paste 174. Electrical component 170c can be similar to semiconductor die 104b from FIG. 1e with bumps 114 oriented toward surface 166 of interposer substrate 160. Alternatively, electrical components 170a-170c can include other semiconductor die, semiconductor packages, surface mount devices, discrete electrical devices, or IPDs. Bumps 114 are brought into contact with conductive layer 162 and reflowed to make electrical and mechanical interconnect. FIG. 3c shows electrical components 170a-170c disposed on surface 166 of interposer 160 with bumps 114 electrically and mechanically connected to conductive layer 162.

An electrically conductive bump material is deposited on surface 168 over conductive layer 162 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 162 using a suitable attachment or bonding process. In one embodiment, the bump material is reflowed by heating the material above its melting point to form balls or bumps 176. In one embodiment, bump 176 is formed over an under bump metallization (UBM) having a wetting layer, barrier layer, and adhesive layer. Bump 176 can also be compression bonded or thermocompression bonded to conductive layer 162. Bump 176 represents one type of interconnect structure that can be formed over conductive layer 162. The interconnect structure can also use bond wires, conductive paste, stud bump, micro bump, or other electrical interconnect. Electrical components 170a-170c and interposer 160 with bumps 176 from FIG. 3c represent semiconductor assembly 178. In one embodiment, semiconductor assembly 178 incorporates a power management (PMIC), such as electrical component 170c. A PMIC controls the operation of a power device, such as electrical component 152 implemented as an RFIC.

Returning to FIG. 2h, semiconductor assembly 178 from FIG. 3c is disposed over active surface 108 of electrical component 152 from FIG. 2g. Semiconductor assembly 178 is positioned over electrical component 152 using a pick and place operation. Bumps 176 are brought into contact with conductive layer 142 and reflowed to make electrical and mechanical interconnect. FIG. 2i shows semiconductor assembly 178 disposed over surface 108 of electrical component 152 with bumps 176 electrically and mechanically connected to conductive layer 142.

In FIG. 2j, an encapsulant or molding compound 180 is deposited over and around semiconductor assembly 178, electrical component 152, and antenna interposer 150 using a paste printing, compressive molding, transfer molding, liquid encapsulant molding, vacuum lamination, spin coating, or other suitable applicator. Encapsulant 180 can be polymer composite material, such as epoxy resin with filler, epoxy acrylate with filler, or polymer with proper filler. Encapsulant 180 is non-conductive, provides structural support, and environmentally protects the semiconductor device from external elements and contaminants. A portion of encapsulant 180 is removed by grinder 181 to expose area 182 of interposer 160.

In FIG. 2k, mask 184 is disposed in area 182 over interposer 160. Note the separation between mask 184 and surface 185 of encapsulant 180.

Electrical components 152 and 170a-170c may contain IPDs that are susceptible to or generate EMI, RFI, harmonic distortion, and inter-device interference. For example, the IPDs contained within electrical components 152 and 170a-170c provide the electrical characteristics needed for high-frequency applications, such as resonators, high-pass filters, low-pass filters, band-pass filters, symmetric Hi-Q resonant transformers, and tuning capacitors. In another embodiment, electrical components 152 and 170a-170c contain digital circuits switching at a high frequency, which could interfere with the operation of IPDs in the assembly.

To address EMI, RFI, harmonic distortion, and inter-device interference, electromagnetic shielding material 186 is applied over mask 184 and encapsulant 180 covering semiconductor assembly 178 and antenna interposer 150, including side surfaces 188 and 190 of encapsulant 180 and antenna interposer 150, as shown in FIG. 2l. Electromagnetic shielding material 186 can be one or more layers of Al, Cu, Sn, Ni, Au, Ag, or other suitable conductive material. Alternatively, electromagnetic shielding material 186 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

In FIG. 2m, a portion of shielding material 186 over mask 184 is removed by etching, LDA, or grinding operation, leaving an exposed conductive layer 162 on surface 166 of interposer 160. In FIG. 2n, electrical connector 194 with contacts 196 and bump material or conductive paste 198 is disposed over the exposed conductive layer 162 on surface 166 of interposer 160. Bumps 198 are brought into contact with the exposed conductive layer 162 and reflowed or cured to make electrical and mechanical interconnection to the conductive layer. FIG. 2o shows shielding material 186 disposed over encapsulant 184 and electrical connector 194 connected to interposer 160 and antenna interposer 150.

FIG. 2o represents AiP module 200 with double-sided electrical component 152 (active surfaces interconnected by conductive vias 111) disposed between antenna interposer 150 and semiconductor assembly 178 (including PMIC). Electrical component 152 has a larger footprint and accommodates higher density circuits and functionality by nature of its double-sided structure with conductive vias 111 providing connectivity between the two active sides 108 and 110. By stacking semiconductor assembly 178 over electrical component 152, and electrical component 152 over antenna interposer 150, AiP module 200 accommodates a large electric component 152, while minimizing overall package size.

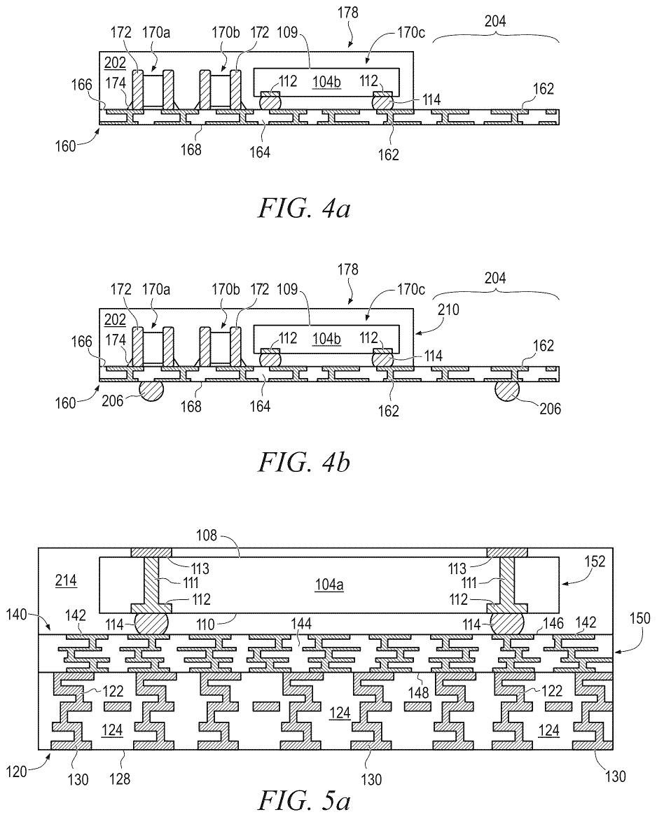

In another embodiment, continuing from FIG. 3c, an encapsulant or molding compound 202 is deposited over and around semiconductor assembly 178 using a paste printing, compressive molding, transfer molding, liquid encapsulant molding, vacuum lamination, spin coating, or other suitable applicator, as shown in FIG. 4a. Components having a similar function are assigned the same reference number. Encapsulant 202 can be polymer composite material, such as epoxy resin with filler, epoxy acrylate with filler, or polymer with proper filler. Encapsulant 202 is non-conductive, provides structural support, and environmentally protects the semiconductor device from external elements and contaminants. A portion of encapsulant 202 is removed by grinding, similar to FIG. 2j, to expose area 204 of interposer 160. Semiconductor assembly 178 with encapsulant 202 constitutes semiconductor assembly 210. In one embodiment, semiconductor assembly 210 incorporates a PMIC, such as electrical component 170c. The PMIC controls a power device, such as electrical component 152 implementing an RFIC.

In FIG. 4b, an electrically conductive bump material is deposited on surface 168 over conductive layer 162 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 162 using a suitable attachment or bonding process. In one embodiment, the bump material is reflowed by heating the material above its melting point to form balls or bumps 206. In one embodiment, bump 206 is formed over a UBM having a wetting layer, barrier layer, and adhesive layer. Bump 206 can also be compression bonded or thermocompression bonded to conductive layer 162. Bump 206 represents one type of interconnect structure that can be formed over conductive layer 162. The interconnect structure can also use bond wires, conductive paste, stud bump, micro bump, or other electrical interconnect. Electrical components 170a-170c and interposer 160 with bumps 206 from FIG. 4b represent semiconductor assembly 210. In one embodiment, semiconductor assembly 210 incorporates a PMIC, such as electrical component 170c.

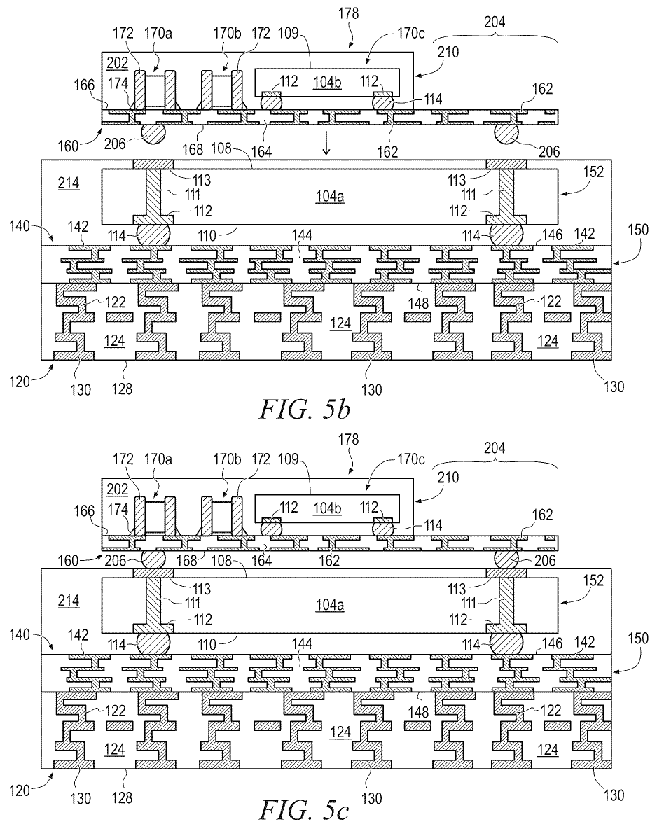

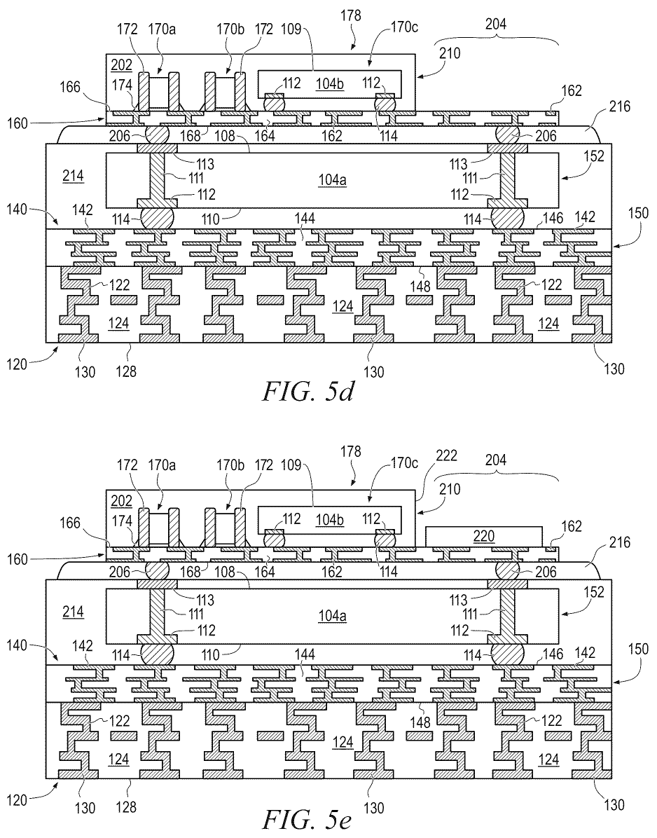

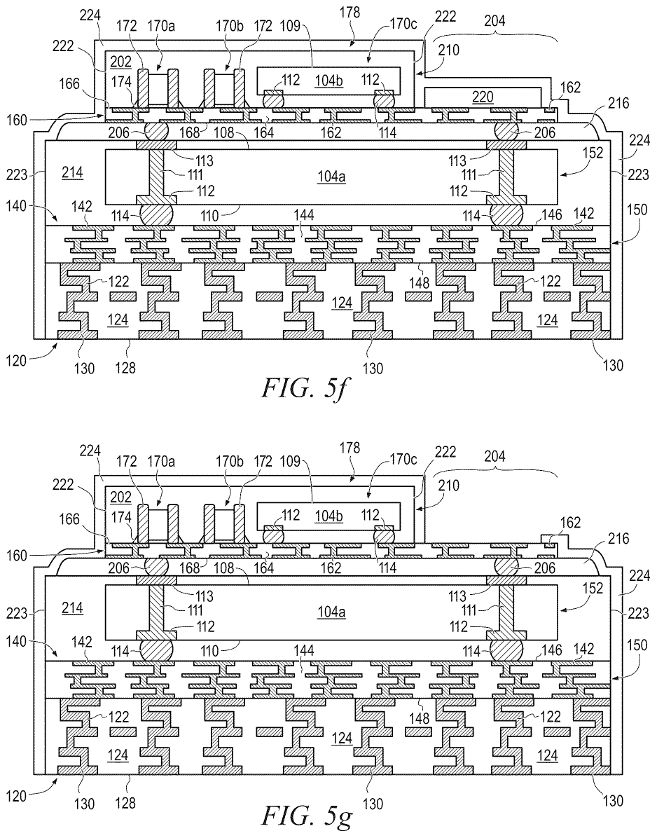

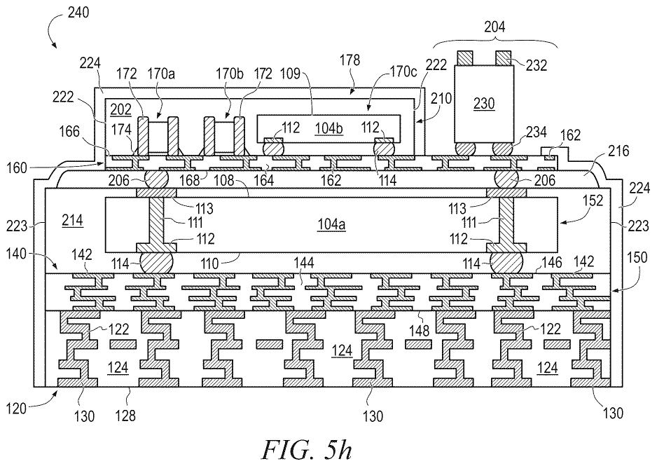

Continuing from FIG. 2g, an encapsulant or molding compound 214 is deposited over and around electrical component 152 and antenna interposer 150 using a paste printing, compressive molding, transfer molding, liquid encapsulant molding, vacuum lamination, spin coating, or other suitable applicator, as shown in FIG. 5a. Encapsulant 214 can be polymer composite material, such as epoxy resin with filler, epoxy acrylate with filler, or polymer with proper filler. Encapsulant 214 is non-conductive, provides structural support, and environmentally protects the semiconductor device from external elements and contaminants.

In FIG. 5b, semiconductor assembly 210 from FIG. 4 is disposed over active surface 108 of electrical component 152 from FIG. 5a. Semiconductor assembly 210 is positioned over electrical component 152 using a pick and place operation. Bumps 206 are brought into contact with conductive layer 142 and reflowed to make electrical and mechanical interconnect. FIG. 5c shows semiconductor assembly 210 disposed over surface 108 of electrical component 152 with bumps 206 electrically and mechanically connected to conductive layer 142.

In FIG. 5d, an underfill material 216, such as an epoxy resin, is deposited between semiconductor assembly 210 and electrical component 152.

In FIG. 5e, mask 220 is disposed in area 204 over interposer 160. Note the separation between mask 220 and surface 222 of encapsulant 202.

Electrical components 152 and 170a-170c may contain IPDs that are susceptible to or generate EMI, RFI, harmonic distortion, and inter-device interference. For example, the IPDs contained within electrical components 152 and 170a-170c provide the electrical characteristics needed for high-frequency applications, such as resonators, high-pass filters, low-pass filters, band-pass filters, symmetric Hi-Q resonant transformers, and tuning capacitors. In another embodiment, electrical components 152 and 170a-170c contain digital circuits switching at a high frequency, which could interfere with the operation of IPDs in the assembly.

To address EMI, RFI, harmonic distortion, and inter-device interference, electromagnetic shielding material 224 is applied over mask 220 and encapsulant 202 and encapsulant 214 covering semiconductor assembly 210 and antenna interposer 150, including side surface 222 of encapsulant 202 and side surface 223 of encapsulant 214, as shown in FIG. 5f. Electromagnetic shielding material 224 can be one or more layers of Al, Cu, Sn, Ni, Au, Ag, or other suitable conductive material. Alternatively, electromagnetic shielding material 224 can be carbonyl iron, stainless steel, nickel silver, low-carbon steel, silicon-iron steel, foil, conductive resin, carbon-black, aluminum flake, and other metals and composites capable of reducing or inhibiting the effects of EMI, RFI, and other inter-device interference.

In FIG. 5g, a portion of shielding material 224 over mask 220 is removed by etching, LDA, or grinding operation, leaving an exposed conductive layer 162 on surface 166 of interposer 160. In FIG. 5h, electrical connector 230 with contacts 232 and bump material or conductive paste 234 is disposed over the exposed conductive layer 162 on surface 166 of interposer 160, similar to FIG. 2n. Bumps 234 are brought into contact with the exposed conductive layer 162 and reflowed or cured to make electrical and mechanical interconnection to the conductive layer.

FIG. 5h represents AiP module 240 with double-sided electrical component 152 (interconnected by conductive vias 111) disposed between antenna interposer 150 and semiconductor assembly 210 (including PMIC). Electrical component 152 has a larger footprint and accommodates higher density circuits and functionality by nature of its double-sided structure with conductive vias 111 providing connectivity between the two active sides 108 and 110. By stacking semiconductor assembly 210 over electrical component 152, and electrical component 152 over antenna interposer 150, AiP module 240 accommodates a large electric component 152, while minimizing overall package size.

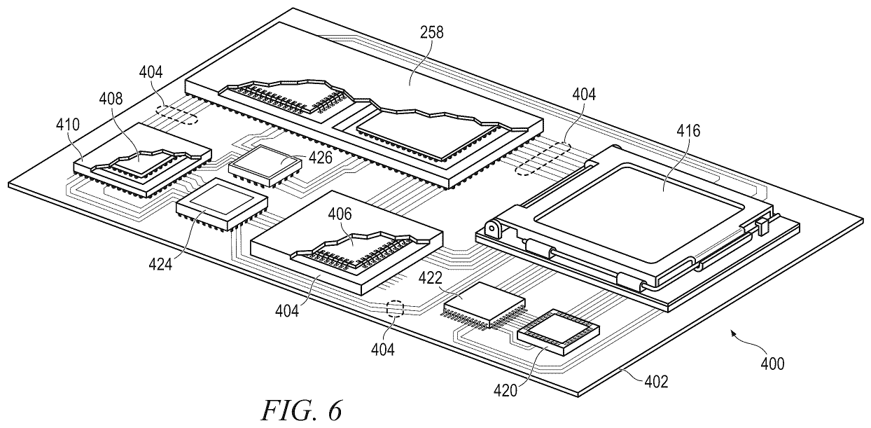

FIG. 6 illustrates electrical device 400 having a chip carrier substrate or PCB 402 with a plurality of semiconductor packages disposed on a surface of PCB 402, including AiP modules 200 and 240. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 6, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an antenna substrate;
an electrical component disposed over the antenna substrate, wherein the electrical component includes a first active surface and second active surface opposite the first active surface with a conductive via extending between the first active surface and second active surface; and
a semiconductor assembly disposed over the electrical component.

2. The semiconductor device of claim 1, further including an encapsulant deposited over and around the antenna substate and electrical component.

3. The semiconductor device of claim 1, further including an encapsulant deposited over the semiconductor assembly.

4. The semiconductor device of claim 1, further including a shielding layer disposed over and around the antenna substate, electrical component, and semiconductor assembly.

5. The semiconductor device of claim 1, further including an electrical connector disposed over the semiconductor assembly.

6. The semiconductor device of claim 1, further including a mask disposed over the semiconductor assembly.

7. A semiconductor device, comprising:
an antenna substrate;
an electrical component disposed over the antenna substrate; and
a semiconductor assembly disposed over the electrical component.

8. The semiconductor device of claim 7, wherein the electrical component includes a first active surface and second active surface opposite the first active surface with a conductive via extending between the first active surface and second active surface.

9. The semiconductor device of claim 7, further including an encapsulant deposited over and around the antenna substate and electrical component.

10. The semiconductor device of claim 7, further including an encapsulant deposited over the semiconductor assembly.

11. The semiconductor device of claim 7, further including a shielding layer disposed over and around the antenna substate, first electrical component, and semiconductor assembly.

12. The semiconductor device of claim 7, further including an electrical connector disposed over the semiconductor assembly.

13. The semiconductor device of claim 7, further including a mask disposed over the semiconductor assembly.

14. A method of making a semiconductor device, comprising:
providing an antenna substrate;
disposing an electrical component over the antenna substrate, wherein the electrical component includes a first active surface and second active surface opposite the first active surface with a conductive via extending between the first active surface and second active surface; and
disposing a semiconductor assembly over the electrical component.

15. The method of claim 14, further including depositing an encapsulant over and around the antenna substate and electrical component.

16. The method of claim 14, further including depositing an encapsulant over the semiconductor assembly.

17. The method of claim 14, further including disposing a shielding layer over and around the antenna substate, electrical component, and semiconductor assembly.

18. The method of claim 14, further including disposing an electrical connector over the semiconductor assembly.

19. The method of claim 14, further including disposing a mask over the semiconductor assembly.

20. A method of making a semiconductor device, comprising:
providing an antenna substrate;
disposing an electrical component over the antenna substrate; and
disposing a semiconductor assembly over the electrical component.

21. The method of claim 20, wherein the electrical component includes a first active surface and second active surface opposite the first active surface with a conductive via extending between the first active surface and second active surface.

22. The method of claim 20, further including depositing an encapsulant over and around the antenna substate and electrical component.

23. The method of claim 20, further including depositing an encapsulant deposited over the semiconductor assembly.

24. The method of claim 20, further including disposing a shielding layer over and around the antenna substate, first electrical component, and semiconductor assembly.

25. The method of claim 20, further including disposing an electrical connector over the semiconductor assembly.
